(19) United States
(12) Patent Application Publication
(10) Pub. No.: US 2026/0290451 A1
(43) Pub. Date: Sep. 24, 2026

(54) MEMORY INCLUDING VARIABLE RESISTOR

(71) Applicant: SK hynix Inc., Icheon-si (KR)

(72) Inventors: Jae Hyuk PARK, Icheon-si (KR); Myoungsub KIM, Icheon-si (KR); Ung Hee PARK, Icheon-si (KR); Sang Min LEE, Icheon-si (KR)

(21) Appl. No.: 19/356,721

(22) Filed: Oct. 13, 2025

(30) Foreign Application Priority Data
Mar. 19, 2025 (KR) 10-2025-0035421

(51) Int. Cl. G11C 13/00; H10N 70/00

(52) U.S. Cl. CPC G11C 13/004; G11C 13/0026; G11C 13/0028; G11C 13/0069; H10N 70/026; H10N 70/841; G11C 2013/0045; G11C 2013/009

(57) ABSTRACT

A memory includes a first word line electrode; a second word line electrode; a first write line electrode disposed between the first word line electrode and the second word line electrode; a variable resistance layer extending to be coupled to the first word line electrode, the second word line electrode, and the first write line electrode; and a bit line electrode disposed on the variable resistance layer and extending along the variable resistance layer.

### CROSS-REFERENCE TO RELATED APPLICATION

This application claims priority under 35 U.S.C. §119 to Korean Patent Application No. 10-2025-0035421, filed on Mar. 19, 2025, the disclosure of which is incorporated herein by reference in its entirety.

### BACKGROUND

### 1. Technical Field

Various embodiments of the present disclosure relate to a memory, and more particularly, to a memory including a variable resistor.

### 2. Related Art

Recently, with the trend of electronic devices toward miniaturization, low power consumption, high performance, and multi-functionality, memories capable of storing information in various electronic devices such as a computer and a portable communication device have been desirable in the art, and research has been conducted for the memories having various characteristics.

Such memories include memories which can store data using a characteristic of having different resistant states according to an applied voltage or current, for example, an RRAM (resistive random access memory), a PRAM (phase-change random access memory), an FRAM (ferroelectric random access memory), an MRAM (magnetic random access memory), an E-fuse, an SOM (selector only memory), etc.

### SUMMARY

In accordance with an embodiment of the present disclosure, a memory may include: a first word line electrode; a second word line electrode; a first write line electrode disposed between the first word line electrode and the second word line electrode; a variable resistance layer extending to be coupled to the first word line electrode, the second word line electrode and the first write line electrode; and a bit line electrode disposed on the variable resistance layer and extending along the variable resistance layer.

In accordance with an embodiment of the present disclosure, a memory may include: a stack including a first word line electrode, a first write line electrode, and a second word line electrode, which are sequentially stacked; a variable resistance layer extending in a vertical direction along a sidewall of the stack; and a bit line electrode extending in the vertical direction along a surface of the variable resistance layer.

In accordance with an embodiment of the present disclosure, a memory may include: a first word line electrode extending in a first direction; a second word line electrode extending in the first direction; a first write line electrode extending in the first direction between the first word line electrode and the second word line electrode; a variable resistance layer disposed on the first word line electrode, the second word line electrode, and the first write line electrode; and a bit line electrode disposed on the variable resistance layer and extending in a second direction crossing the first direction.

In accordance with an embodiment of the present disclosure, a memory may include: a first memory cell including a first electrode, a common electrode, and a first portion of a variable resistance layer, the first electrode extending in a first direction, the common electrode extending in a second direction that crosses the first direction, the variable resistance layer being disposed between the first electrode and the common electrode; a second memory cell including a second electrode, the common electrode, and a second portion of the variable resistance layer, the second electrode extending in the first direction, the second electrode being disposed over the first electrode; and a write line electrode disposed between the first electrode and the second electrode.

### BRIEF DESCRIPTION OF THE DRAWINGS

FIG. 1 is a diagram illustrating a memory cell in accordance with an embodiment of the present disclosure.

FIG. 2A is a diagram illustrating a memory in accordance with an embodiment of the present disclosure.

FIG. 2B is a diagram illustrating a write operation on a memory cell of the memory illustrated in FIG. 2A, in accordance with an embodiment of the present disclosure.

FIG. 2C is a diagram illustrating a read operation on a memory cell of the memory illustrated in FIG. 2A, in accordance with an embodiment of the present disclosure.

FIG. 3 is a diagram illustrating a memory in accordance with an embodiment of the present disclosure.

FIG. 4 is a diagram illustrating a memory in accordance with an embodiment of the present disclosure.

FIG. 5 is a diagram illustrating a memory in accordance with an embodiment of the present disclosure.

### DETAILED DESCRIPTION

Various embodiments of the present disclosure are directed to technology of increasing a degree of integration of a memory.

According to embodiments of the present disclosure, it is possible to increase a degree of integration of a memory.

Hereinafter, some embodiments of the present disclosure are described below with reference to the accompanying drawings.

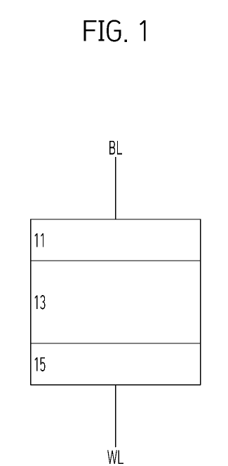

FIG. 1 is a diagram illustrating a memory cell in accordance with an embodiment of the present disclosure.

Referring to FIG. 1, the memory cell may include electrodes 11 and 15 and a variable resistance layer 13 between the electrodes 11 and 15.

Because a bit line BL is connected to the electrode 11, the electrode 11 may be also referred to as a bit line electrode. Because a word line WL is connected to the electrode 15, the electrode may also be referred to as a word line electrode.

The variable resistance layer 13 may include a chalcogenide-based dual function material (DFM). The variable resistance layer 13 may store a logic state according to physical and chemical characteristics or properties of the DFM. In an embodiment, the memory cell including the variable resistance layer 13 may be a selector only memory (SOM) cell or a self-selecting memory (SSM) cell. The variable resistance layer 13 may have a threshold voltage level that changes depending on one or more of a direction of a current flowing through the variable resistance layer 13, a magnitude of the current, a number of times the current flows, and the like.

A write operation of the memory cell may be an operation of applying a voltage to the bit line electrode 11 and the word line electrode 15 such that a voltage difference between the bit line electrode 11 and the word line electrode 15 is greater than a voltage level at which the variable resistance layer 13 is turned on. When a higher voltage is applied to the bit line electrode 11 than to the word line electrode 15 during the write operation, the characteristics of the variable resistance layer 13 may change so that a current from the bit line electrode 11 to the word line electrode 15 flows better than a current from the word line electrode 15 to the bit line electrode 11. On the other hand, when a higher voltage is applied to the word line electrode 15 than to the bit line electrode 11 during the write operation, the characteristics of the variable resistance layer 13 may change so that the current from the word line electrode 15 to the bit line electrode 11 flows better than the current from the bit line electrode 11 to the word line electrode 15.

A read operation of the memory cell may be performed by applying a voltage to the bit line electrode 11 that is higher than a voltage applied to the word line electrode 15 by a read voltage Vread and determining whether an amount of current flowing from the bit line electrode 11 to the word line electrode 15 is greater than or less than a reference value. Alternatively, the read operation may be performed by applying a voltage to the word line electrode 15 that is higher than a voltage applied to the bit line electrode 11 by the read voltage Vread and determining whether an amount of current flowing from the word line electrode 15 to the bit line electrode 11 is greater than or less than the reference value. Because the read operation is for finding out data stored in the variable resistance layer 13 and is not an operation for changing the data stored in the variable resistance layer 13, a voltage difference between the voltages applied to the bit line electrode 11 and the word line electrode 15 during the read operation may be smaller than a voltage difference between the voltages applied to the bit line electrode 11 and the word line electrode 15 during the write operation. For example, a voltage difference between the voltages applied to the bit line electrode 11 and the word line electrode 15 during a read operation may be smaller than a threshold voltage of the memory cell, whereas a voltage difference between the voltages applied to the bit line electrode 11 and the word line electrode 15 during a write operation may be greater than the threshold voltage.

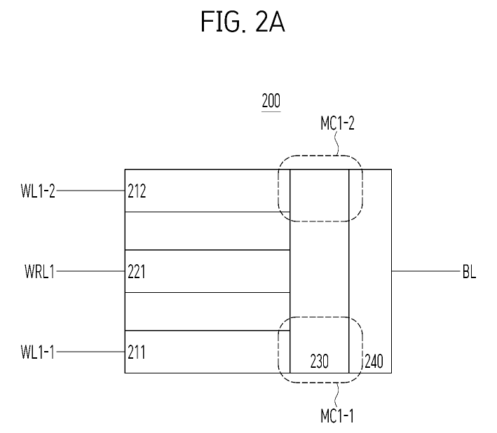

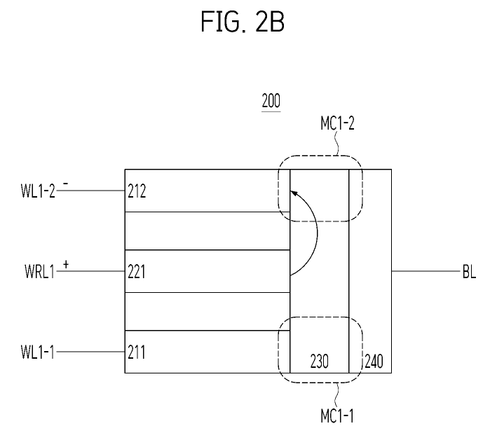

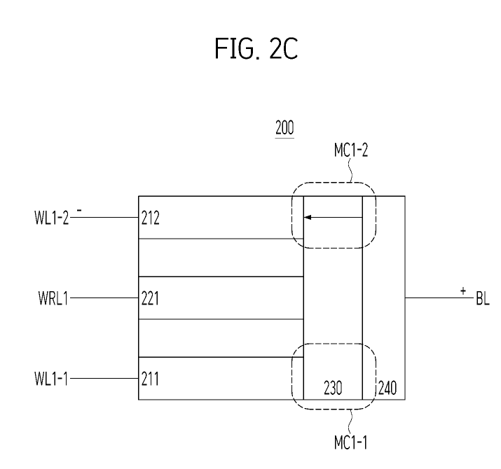

FIG. 2A is a diagram illustrating a memory 200 in accordance with an embodiment of the present disclosure.

Referring to FIG. 2A, the memory 200 may include first and second electrodes (e.g., word line electrodes) 211 and 212, a write line electrode 221, a variable resistance layer 230, and a common electrode (e.g., a bit line electrode) 240. A voltage may be applied to the word line electrodes 211 and 212 through word lines WL1-1 and WL1-2, respectively, a voltage may be applied to the write line electrode 221 through a write line WRL1, and a voltage may be applied to the bit line electrode 240 through a bit line BL.

The word line electrode (or a first word line electrode) 211, the write line electrode 221 and the word line electrode (or a second word line electrode) 212 may be sequentially stacked, and the electrodes 211, 221, and 212 may be electrically isolated by a dielectric. For example, a first dielectric may be disposed between the first word line electrode 211 and the write line electrode 221 to electrically isolate the electrodes 211 and 221 from each other, and a second dielectric may be disposed between the write line electrode 221 and the second word line electrode 212 to electrically isolate the electrodes 221 and 212 from each other. Each of the electrodes 211, 221, and 212 may extend in a first direction (e.g., a horizontal direction), and the second word line electrode 212 may be disposed over the first word line electrode 211.

The variable resistance layer 230 may extend to be coupled to the first word line electrode 211, the write line electrode 221, and the second word line electrode 212. In some embodiments, the variable resistance layer 230 may extend in a specific direction (e.g., a second direction crossing the first direction) along which the first word line electrode 211, the write line electrode 221, and the second word line electrode 212 are stacked. For example, the variable resistance layer 230 may be formed to extend in a vertical direction along a sidewall of a stack in which the electrodes 211, 221, and 212 are stacked. The variable resistance layer 230 may include a chalcogenide-based dual function material (DFM). For example, the variable resistance layer 230 may include an ovonic threshold switch (OTS) material. The variable resistance layer 230 may store a logic state according to physical and chemical characteristics or properties of the DFM. In an embodiment, a memory cell including the variable resistance layer 230 may be a selector only memory (SOM) cell or a self-selecting memory (SSM) cell. The variable resistance layer 230 may have a threshold voltage level that changes depending on one or more of a direction of a current flowing through the variable resistance layer 230, a magnitude of the current, a number of times the current flows, and the like.

The bit line electrode 240 may be formed to extend in the vertical direction along a surface of the variable resistance layer 230.

In the memory 200 of FIG. 2A, two memory cells MC1-1 and MC1-2 are formed. The first word line electrode 211, a first portion of the variable resistance layer 230 in contact with the first word line electrode 211, and the bit line electrode 240 may form a single memory cell (or a first memory cell) MC1-1. The first memory cell MC1-1 may be programmed based on a first voltage difference between a pair of voltages applied to the first word line electrode 211 and the write line electrode 221. The first memory cell MC1-1 may also be read when a read voltage is applied thereto based on an amount of current flowing through the first memory cell MC1-1. The second word line electrode 212, a second portion of the variable resistance layer 230 in contact with the second word line electrode 212, and the bit line electrode 240 may form another memory cell (or a second memory cell) MC1-2. The second memory cell MC1-2 may be programmed based on a second voltage difference between a pair of voltages applied to the write line electrode 221 and the second word line electrode 212. The second memory cell MC1-2 may also be read when a read voltage is applied thereto based on an amount of current flowing through the second memory cell MC1-2. The write line electrode 221 may be shared by the memory cells MC1-1 and MC1-2 and be used for the write operations of the memory cells MC1-1 and MC1-2. In other words, the write line electrode 221 may be commonly coupled to the memory cells MC1-1 and MC1-2 via the variable resistance layer 230 to perform write operations on the memory cells MC1-1 and MC1-2, respectively.

In this case, the write line electrode 221 may function as a kind of victim electrode or victim cell. Elements inside the dual function material forming the variable resistance layer 230 may move due to a voltage difference occurring between the write line electrode 221 and the word line electrode 211 or 212, and such element movement may be based on an electro-thermal migration mechanism.

During the write operation of the memory cell MC1-1 or MC2-1, a direction and an amount of movement each of the elements may be determined according to a voltage condition formed between the write line electrode 221 and the word line electrode 211 or 212 of the corresponding cell, and thus a threshold voltage of the corresponding cell may change. In some embodiments, each of the memory cell MC1-1 and MC2-1 may be programmed to have a desired threshold voltage level by adjusting one or more of a voltage difference between a pair of voltages applied to the write line electrode 221 and a corresponding word line electrode 211 or 212, a time interval for applying the pair of voltages, and a number of times the pair of voltages are applied. For example, the number of times, or magnitude of voltage application, or both, may be adjusted so that different levels of threshold voltage may be implemented.

FIG. 2B is a diagram illustrating a write operation on the memory cell MC1-2 of the memory 200 illustrated in FIG. 2A, in accordance with an embodiment of the present disclosure.

The write operation of the memory cell MC1-2 may be performed using the write line electrode 221 and the word line electrode 212. A first voltage (e.g., a positive voltage +) may be applied to the write line electrode 221 through the write line WRL1, and a second voltage (e.g., a negative voltage-) that is lower than the first voltage may be applied to the word line electrode 212 through the word line WL1-2. In this case, the voltage difference between the electrodes 221 and 212 may be sufficient to change a threshold voltage level of the portion of the variable resistance layer 230 in contact with the word line electrode 212. For example, the voltage difference between voltages applied to the electrodes 221 and 212 may be greater than a threshold voltage of the memory cell MC1-2 to change the threshold voltage.

A current may flow from the write line electrode 221 to the word line electrode 212 through the variable resistance layer 230, and accordingly, the threshold voltage level of the portion of the variable resistance layer 230 in contact with the word line electrode 212 may change. That is, the write operation may be performed.

In the embodiment of FIG. 2B, the high voltage (+) is applied to the write line electrode 221 and the low voltage (-) is applied to the word line electrode 212, but embodiments of the present disclosure are not limited thereto. For example, the high voltage (+) may be applied to the word line electrode 212 and the low voltage (-) may be applied to the write line electrode 221, so that the write operation of the memory cell MC1-2 may be performed.

Similarly, a write operation of the memory cell MC1-1 may be performed by applying voltages to the write line electrode 221 and the word line electrode 211.

FIG. 2C is a diagram illustrating a read operation on the memory cell MC1-2 of the memory 200 illustrated in FIG. 2A, in accordance with an embodiment of the present disclosure.

The read operation of the memory cell MC1-2 may be performed using the bit line electrode 240 and the word line electrode 212. A first voltage (e.g., a positive voltage +) may be applied to the bit line electrode 240 through the bit line BL, and a second voltage (e.g., a negative voltage -) that is lower than the first voltage may be applied to the word line electrode 212 through the word line WL1-2. In this case, the voltage difference between the electrodes 240 and 212 may be small enough not to change the threshold voltage of the variable resistance layer 230. For example, the voltage difference between voltages applied to the electrodes 240 and 212 may be smaller than a threshold voltage of the memory cell MC1-2 to substantially maintain the threshold voltage. In some embodiments, when the variable resistance layer 230 of the memory cell MC1-2 includes an OTS material and the voltage difference smaller than a threshold voltage of the memory cell MC1-2 is applied thereto in a read operation, a relatively small amount of current flows through the memory cell MC1-2, which corresponds to relatively low conductance of the memory cell MC1-2, resulting in relatively low power consumption.

As the amount of current flowing from the bit line electrode 240 to the word line electrode 212 through the variable resistance layer 230 is sensed while the voltages are applied to the bit line electrode 240 and the word line electrode 212, data stored in the memory cell MC1-2 may be sensed.

In the embodiment of FIG. 2C, the high voltage (+) is applied to the bit line electrode 240 and the low voltage (-) is applied to the word line electrode 212, but embodiments of the present disclosure are not limited thereto. For example, the high voltage (+) may be applied to the word line electrode 212 and the low voltage (-) may be applied to the bit line electrode 240, so that the read operation of the memory cell MC1-2 may be performed.

The read operation of the memory cell MC1-1 may be performed by applying voltages to the bit line electrode 240 and the word line electrode 211 and sensing the amount of current flowing through the bit line electrode 240.

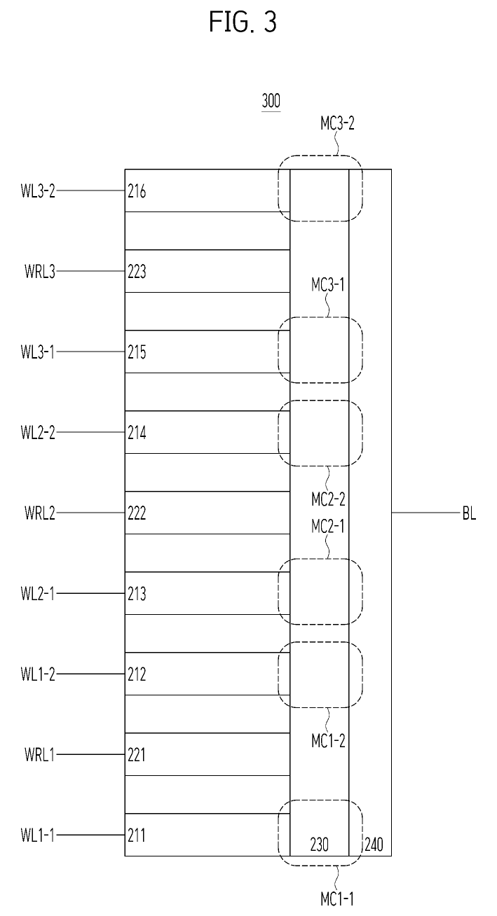

FIG. 3 is a diagram illustrating a memory 300 in accordance with an embodiment of the present disclosure.

FIG. 3 illustrates that a larger number of memory cells MC1-1, MC1-2, MC2-1, MC2-2, MC3-1 and MC3-2 are vertically stacked, compared to the memory 200 of FIG. 2A.

A number of word line electrodes 211, 212, 213, 214, 215, and 216 may be provided as same as a number of the memory cells MC1-1, MC1-2, MC2-1, MC2-2, MC3-1, and MC3-2, and write line electrodes 221 to 223 may be provided one for each two memory cells. In addition, the word line electrodes 211 to 216 and the write line electrodes 221 to 223 may be sequentially stacked, such that a single write line electrode (e.g., 222) may be disposed between a pair of adjacent word line electrodes (e.g., 213 and 214).

A variable resistance layer 230 may extend to be coupled to the stacked electrodes 211, 221, 212, 213, 222, 214, 215, 223, and 216. In some embodiments, the variable resistance layer 230 may extend in a specific direction along which the electrodes 211, 221, 212, 213, 222, 214, 215, 223, and 216 are stacked. For example, the variable resistance layer 230 may be formed to extend in a vertical direction along a sidewall of a stack in which the electrodes 211 to 216 and 221 to 223 are stacked. A bit line electrode 240 may extend along the variable resistance layer 230. For example, the bit line electrode 240 may be formed to extend in the vertical direction along a surface of the variable resistance layer 230.

Write operations of the memory cells MC1-1, MC1-2, MC2-1, MC2-2, MC3-1 and MC3-2 may be performed using the write line electrodes 221 to 223 and the word line electrodes 211 to 216. For example, the write operation of the memory cell MC2-2 may be performed by applying voltages having a relatively large voltage difference to the write line electrode 222 and the word line electrode 214, and the write operation of the memory cell MC3-1 may be performed by applying voltages having a relatively large voltage difference to the write line electrode 223 and the word line electrode 215. For example, such a relatively large voltage difference to perform a write operation may be greater than a threshold voltage of a corresponding one of the memory cells MC2-2 and MC3-1.

Read operations of the memory cells MC1-1, MC1-2, MC2-1, MC2-2, MC3-1 and MC3-2 may be performed using the word line electrodes 211 to 216 and the bit line electrode 240. For example, the read operation of the memory cell MC2-2 may be performed by applying voltages having a relatively small voltage difference to the word line electrode 214 and the bit line electrode 240 and sensing an amount of current flowing through the bit line electrode 240 to sense data stored in the memory cell MC2-2. In addition, the read operation of the memory cell MC3-1 may be performed by applying voltages having a relatively small voltage difference to the word line electrode 215 and the bit line electrode 240 and sensing the amount of current flowing through the bit line electrode 240 to sense data stored in the memory cell MC3-1. For example, such a relatively small voltage difference to perform a read operation may be smaller than a threshold voltage of a corresponding one of the memory cells MC2-2 and MC3-1.

FIG. 3 illustrates six memory cells MC1-1, MC1-2, MC2-1, MC2-2, MC3-1 and MC3-2 that are vertically stacked, but a number of stacked memory cells may vary according to embodiments. As a plurality of memory cells are vertically stacked as illustrated in FIG. 3, a degree of integration of the memory may increase.

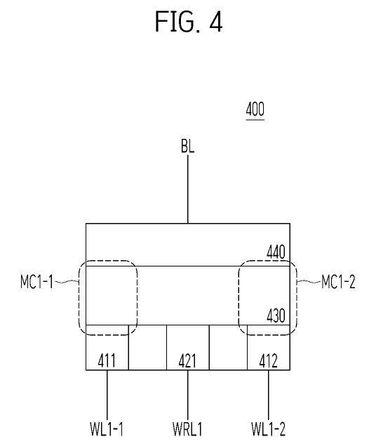

FIG. 4 is a diagram illustrating a memory 400 in accordance with an embodiment of the present disclosure.

FIG. 4 illustrates that memory cells MC1-1 and MC1-2 in the memory 200 of FIG. 2A are not vertically stacked, but are arranged in a planar manner.

Referring to FIG. 4, the memory 400 may include word line electrodes 411 and 412, a write line electrode 421, a variable resistance layer 430, and a bit line electrode 440. For example, each of the word line electrode (or a first word line electrode) 411, the word line electrode (or a second word line electrode) 412, and the write line electrode 421 may extend in a first direction. The variable resistance layer 430 may be disposed on the word line electrodes 411 and 412 and the write line electrode 421 and extend in a second direction crossing the first direction. A voltage may be applied to the word line electrodes 411 and 412 through word lines WL1-1 and WL1-2, respectively, a voltage may be applied to the write line electrode 421 through word line WRL1, and a voltage may be applied to the bit line electrode 440 through a bit line BL.

The word line electrode 411, the write line electrode 421 and the word line electrode 412 may be arranged in sequence, and the electrodes 411, 421 and 412 may be electrically isolated by a dielectric. For example, a first dielectric may be disposed between the first word line electrode 411 and the write line electrode 421 to electrically isolate the electrodes 411 and 421 from each other, and a second dielectric may be disposed between the write line electrode 421 and the second word line electrode 412 to electrically isolate the electrodes 421 and 412 from each other.

The variable resistance layer 430 may be disposed on the electrodes 411, 421 and 412. The variable resistance layer 430 may include a chalcogenide-based dual function material (DFM). The variable resistance layer 430 may store a logic state according to physical and chemical characteristics or properties of the DFM. In an embodiment, a memory cell including the variable resistance layer 430 may be a selector only memory (SOM) cell or a self-selecting memory (SSM) cell. The variable resistance layer 430 may have a threshold voltage level that changes depending on one or more of a direction of a current flowing through the variable resistance layer 430, a magnitude of the current, a number of times the current flows, and the like.

The bit line electrode 440 may be disposed on the variable resistance layer 430 and extend in the second direction that crosses the first direction.

Write operations of the memory cells MC1-1 and MC1-2 may be performed using the write line electrode 421 and the word line electrodes 411 and 412. For example, the first memory cell MC1-1 may include the word line electrode 411, a portion of the variable resistance layer 430 in contact with the word line electrode 411, and the bit line electrode 440, and is configured to be programmed based on a voltage difference between voltages applied to the write line electrode 421 and the word line electrode 411. The write operation of the memory cell MC1-1 may be performed by applying voltages having a relatively large voltage difference to the write line electrode 421 and the word line electrode 411, and the write operation of the memory cell MC1-2 may be performed by applying voltages having a relatively large voltage difference to the write line electrode 421 and the word line electrode 412.

Read operations of the memory cells MC1-1 and MC1-2 may be performed using the bit line electrode 440 and the word line electrodes 411 and 412. For example, data stored in the first memory cell MC1-1 may be read based on an amount of current flowing through the first memory cell MC1-1. The read operation of the memory cell MC1-1 may be performed by applying voltages having a relatively small voltage difference to the word line electrode 411 and the bit line electrode 440 and sensing an amount of current flowing through the bit line electrode 440. The read operation of the memory cell MC2-1 may be performed by applying voltages having a relatively small voltage difference to the word line electrode 412 and the bit line electrode 440 and sensing the amount of current flowing through the bit line electrode 440.

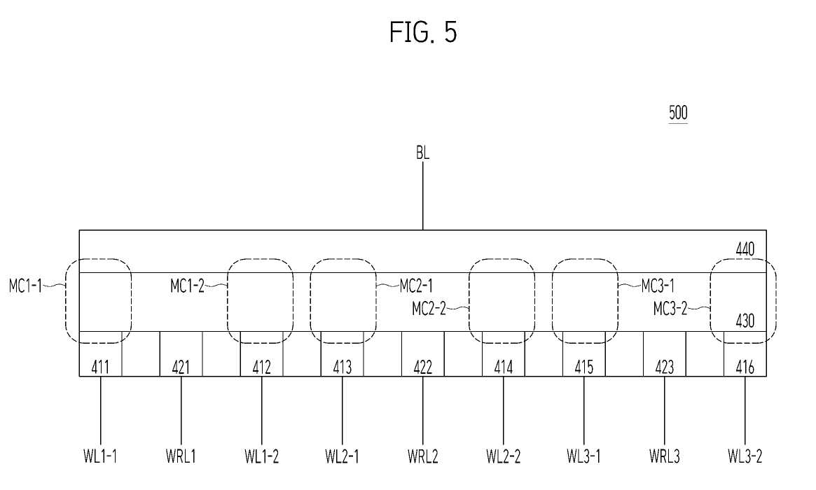

FIG. 5 is a diagram illustrating a memory 500 in accordance with an embodiment of the present disclosure.

FIG. 5 illustrates that a larger number of memory cells MC1-1, MC1-2, MC2-1, MC2-2, MC3-1, and MC3-2 compared to the memory 400 of FIG. 4 are arranged in a planar manner.

Word line electrodes 411, 412, 413, 414, 415, and 416 may be provided as same as a number of the memory cells MC1-1, MC1-2, MC2-1, MC2-2, MC3-1 and MC3-2, and write line electrodes 421 to 423 may be provided one for each two memory cells. In addition, the word line electrodes 411 to 416 and the write line electrodes 421 to 423 may be sequentially stacked, such that a single write line electrode (e.g., 422) may be disposed between a pair of adjacent word line electrodes (e.g., 413, and 414).

A variable resistance layer 430 may be disposed on the electrodes 411 to 416 and 421 to 423. A bit line electrode 440 may be disposed on the variable resistance layer 430.

Write operations of the memory cells MC1-1, MC1-2, MC2-1, MC2-2, MC3-1 and MC3-2 may be performed using the write line electrodes 421 to 423 and the word line electrodes 411 to 416. For example, the write operation of the memory cell MC2-2 may be performed by applying voltages having a relatively large voltage difference to the write line electrode 422 and the word line electrode 414, and the write operation of the memory cell MC3-1 may be performed by applying voltages having a relatively large voltage difference to the write line electrode 423 and the word line electrode 415.

Read operations of the memory cells MC1-1, MC1-2, MC2-1, MC2-2, MC3-1 and MC3-2 may be performed using the word line electrodes 411 to 416 and the bit line electrode 440. For example, the read operation of the memory cell MC2-2 may be performed by applying voltages having a relatively small voltage difference to the word line electrode 414 and the bit line electrode 440 and sensing an amount of current flowing through the bit line electrode 440 to sense data stored in the memory cell MC2-2. In addition, the read operation of the memory cell MC3-1 may be performed by applying voltages having a relatively small voltage difference to the word line electrode 415 and the bit line electrode 440 and sensing the amount of current flowing through the bit line electrode 440 to sense data stored in the memory cell MC3-1.

FIG. 5 illustrates that six memory cells MC1-1, MC1-2, MC2-1, MC2-2, MC3-1 and MC3-2 are arranged in the planar manner, but a number of arranged memory cells may vary according to embodiments.

Although some embodiments of the present disclosure have been described above, various embodiments of the present disclosure are not limited to the above-described embodiments. Various modifications may be possible.

What is claimed is:

1. A memory comprising:
a first word line electrode;
a second word line electrode;
a first write line electrode disposed between the first word line electrode and the second word line electrode;
a variable resistance layer extending to be coupled to the first word line electrode, the second word line electrode, and the first write line electrode; and
a bit line electrode disposed on the variable resistance layer and extending along the variable resistance layer.

2. The memory of claim 1, further comprising:
a first dielectric configured to electrically isolate the first word line electrode and the first write line electrode; and
a second dielectric configured to electrically isolate the first write line electrode and the second word line electrode.

3. The memory of claim 1, wherein a first memory cell includes the first word line electrode, a first portion of the variable resistance layer in contact with the first word line electrode, and the bit line electrode, and is configured to be programmed based on a first voltage difference between a pair of first voltages applied to the first write line electrode and the first word line electrode, and
wherein a second memory cell includes the second word line electrode, a second portion of the variable resistance layer in contact with the second word line electrode, and the bit line electrode, and is configured to be programmed based on a second voltage difference between a pair of second voltages applied to the first write line electrode and the second word line electrode.

4. The memory of claim 3, wherein the first memory cell including the first portion of the variable resistance layer is configured to be programmed to have a first desired threshold voltage level by adjusting one or more of the first voltage difference between the pair of first voltages, a time interval for applying the pair of first voltages, and a number of times the pair of first voltages are applied, and
wherein the second memory cell including the second portion of the variable resistance layer is configured to be programmed to have a second desired threshold voltage level by adjusting one or more of the second voltage difference between the pair of second voltages , a time interval for applying the pair of second voltages, and a number of times the pair of second voltages are applied.

5. The memory of claim 1, wherein a first memory cell includes the first word line electrode, a first portion of the variable resistance layer in contact with the first word line electrode, and the bit line electrode, and is configured to be read when a read voltage is applied thereto based on an amount of current flowing through the first memory cell, and
wherein a second memory cell includes the second word line electrode, a second portion of the variable resistance layer in contact with the second word line electrode, and the bit line electrode, and is configured to be read when the read voltage is applied thereto based on an amount of current flowing through the second memory cell.

6. The memory of claim 1, further comprising:
a third word line electrode;
a fourth word line electrode; and
a second write line electrode disposed between the third word line electrode and the fourth word line electrode,
wherein the variable resistance layer further extends to be coupled to the third word line electrode, the fourth word line electrode, and the second write line electrode.

7. A memory comprising:
a stack including a first word line electrode, a first write line electrode, and a second word line electrode, which are sequentially stacked;
a variable resistance layer extending in a specific direction along which the first word line electrode, the first write line electrode, and the second word line electrode are stacked; and
a bit line electrode extending along the variable resistance layer.

8. The memory of claim 7, further comprising:
a first dielectric configured to electrically isolate the first word line electrode and the first write line electrode; and
a second dielectric configured to electrically isolate the first write line electrode and the second word line electrode.

9. The memory of claim 7, wherein a memory cell includes the first word line electrode, a portion of the variable resistance layer in contact with the first word line electrode, and the bit line electrode, and is configured to be programmed based on a voltage difference between voltages applied to the first write line electrode and the first word line electrode.

10. The memory of claim 7, wherein a memory cell includes the first word line electrode, a portion of the variable resistance layer in contact with the first word line electrode, and the bit line electrode, and is configured to be read based on an amount of current flowing through the memory cell.

11. The memory of claim 7, wherein the stack further includes a third word line electrode, a second write line electrode, and a fourth word line electrode, which are sequentially stacked, and
wherein the variable resistance layer further extends to be coupled to the third word line electrode, the second write line electrode, and the fourth word line electrode.

12. A memory comprising:
a first word line electrode extending in a first direction;
a second word line electrode extending in the first direction;
a first write line electrode extending in the first direction between the first word line electrode and the second word line electrode;
a variable resistance layer disposed on the first word line electrode, the second word line electrode, and the first write line electrode; and
a bit line electrode disposed on the variable resistance layer and extending in a second direction that crosses the first direction.

13. The memory of claim 12, further comprising:
a first dielectric configured to electrically isolate the first word line electrode and the first write line electrode, and extending in the first direction; and
a second dielectric configured to electrically isolate the first write line electrode and the second word line electrode, and extending in the first direction.

14. The memory of claim 12, wherein a memory cell includes the first word line electrode, a portion of the variable resistance layer in contact with the first word line electrode, and the bit line electrode, and is configured to be programmed based on a voltage difference between voltages applied to the first write line electrode and the first word line electrode.

15. The memory of claim 12, wherein a memory cell includes the first word line electrode, a portion of the variable resistance layer in contact with the first word line electrode, and the bit line electrode, and is configured to be read based on an amount of current flowing through the memory cell.

16. The memory of claim 12, further comprising:
a third word line electrode extending in the first direction;
a fourth word line electrode extending in the first direction; and
a second write line electrode extending in the first direction between the third word line electrode and the fourth word line electrode,
wherein the variable resistance layer is further disposed on the third word line electrode, the fourth word line electrode, and the second write line electrode.

17. A memory comprising:
a first memory cell including a first electrode, a common electrode, and a first portion of a variable resistance layer, the first electrode extending in a first direction, the common electrode extending in a second direction that crosses the first direction, the variable resistance layer being disposed between the first electrode and the common electrode;
a second memory cell including a second electrode, the common electrode, and a second portion of the variable resistance layer, the second electrode extending in the first direction, the second electrode being disposed over the first electrode; and
a write line electrode disposed between the first electrode and the second electrode.

18. The memory of claim 17, wherein the first electrode is a first word line electrode, the common electrode is a bit line electrode, and the second electrode is a second word line electrode.

19. The memory of claim 18, wherein the first memory cell is configured to be programmed based on a voltage difference between a pair of first voltages applied to the write line electrode and the first word line electrode, and
wherein the second memory cell is configured to be programmed based on a voltage difference between a pair of second voltages applied to the write line electrode and the second word line electrode.

20. The memory of claim 18, wherein the first memory cell is configured to be read when a read voltage is applied thereto based on an amount of current flowing through the first memory cell, and
wherein the second memory cell is configured to be read when the read voltage is applied thereto based on an amount of current flowing through the second memory cell.
